(19) United States
(12) Patent Application Publication
(10) Pub. No.: US 2013/0050959 A1
(43) Pub. Date: Feb. 28, 2013

(54) WIRELESS MODULE WITH EXTERNAL ANTENNA AND CONNECTOR HAVING THE SAME

(71) Applicant: Nai-Chien CHANG, New Taipei City (TW)

(72) Inventor: Nai-Chien CHANG, New Taipei City (TW)

(21) Appl. No.: 13/480,155

(22) Filed: May 24, 2012

(30) Foreign Application Priority Data
Aug. 31, 2011 (TW) 100216231

(51) Int. Cl. H05K 7/16

(52) U.S. Cl. 361/736

(57) ABSTRACT

A wireless module with an external antenna and a connector with the wireless module are disclosed. The wireless module includes a printed circuit board, a plurality of conductive terminals, a wireless transmission chip, an antenna connector and an external antenna. The plurality of conductive terminals, the wireless transmission chip, and the antenna connector are electrically coupled to a printed circuit board, and the external antenna is coupled to the antenna connector through a connected circuit. The wireless module further includes a casing for covering the printed circuit board, the conductive terminals, the wireless transmission chip, and the antenna connector. A pivot hinge is installed at an end of the casing, and the external antenna is pivotally coupled to the pivot hinge of the casing, so that users can change the angle of the external antenna to adjust the intensity and range of receiving/transmitting signals of the wireless module freely.

### FIELD OF THE INVENTION

The present invention relates to a wireless module, in particular to a wireless module with an external antenna installed thereon, and a connector having the wireless module for enhancing the intensity and range of receiving and transmitting signals.

### BACKGROUND OF THE INVENTION

As the electronic industry blooms, various electronic devices are continuously developed and introduced in our life. In order to input a control instruction to control the electronic devices or transmit data between several electronic devices, most electronic devices are equipped with a connector.

For example, most present popular personal computers have a plurality of connectors such as Universal Serial Bus (USB) connectors, External Serial Advance Technology Attachment (e-SATA) connectors, RJ-45 connectors, and High Definition Multimedia Interface (HDMI) connectors, so that an external device can be connected through a transmission line to receive control instructions, or connected to another electronic device through the transmission line to transmit data between several electronic devices.

In recent years, new models of electronic devices are further equipped with a wireless transmission module such as a radio frequency (RF) module, an infrared ray (IR) module, a Bluetooth module, or a wireless fidelity (Wi-Fi) module to waive the use of the physical transmission line and extend the data transmission distance. Each electronic device can transmit data through the wireless transmission module, not only saving the material and installation costs of the transmission line, but also facilitating the data transmission.

However, the installed connectors or wireless transmission modules occupy much space on a printed circuit board (or motherboard) of the electronic device. If there are too many installed connectors or wireless transmission modules, the precious installation space on the printed circuit board is occupied, thus resulting in a too-large area of the printed circuit board, affecting the circuit layout of the printed circuit board, and increasing the level of difficulty of the production.

Therefore, some designers and manufacturers provided a multi-deck connector that stacks a plurality of connectors or wireless transmission modules vertically on top of one another, such that the printed circuit board just occupies the installation space equal to the size of one connector only. However, the wireless transmission module of such multi-deck connector mainly uses a built-in antenna unit to transmit or receive wireless signals and focuses on a one-way receipt or transmission of the wireless signals, so that the area of the antenna is also affected adversely. As a result, an antenna with a greater coverage cannot be installed, and the wireless transmission module of this sort has the problems of too-short receiving/transmitting range, one-way transmission, and poor signal transmission.

Obviously, a novel wireless transmission module, and a connector having the wireless transmission module are required to overcome the problems of insufficient installation space on the motherboard and the poor receipt/transmission of the wireless signals.

### SUMMARY OF THE INVENTION

Therefore, it is a primary objective of the present invention to provide a wireless module with an external antenna and a connector having the wireless module.

To achieve the aforementioned objective, the present invention provides a wireless module capable of enhancing the intensity and range of receiving/transmitting signals through an external antenna and adjusting the angle of the external antenna through a pivot hinge freely.

To achieve the aforementioned objective, the present invention provides a wireless module with an external antenna, comprising: a printed circuit board, a plurality of conductive terminals, a wireless transmission chip, an antenna connector and an external antenna, wherein the plurality of conductive terminals, the wireless transmission chip, and the antenna connector are electrically coupled to a printed circuit board, and the external antenna is coupled to an antenna connector through a connected circuit, and the wireless module further comprises a casing for covering the printed circuit board, the plurality of conductive terminals, the wireless transmission chip, and the antenna connector. A pivot hinge is installed at an end of the casing, and the external antenna is pivotally coupled to the pivot hinge of the casing.

Compared with the prior art, the present invention has the advantages and effects of enhancing the signal receiving range of the wireless module through the external antenna, improving the receiving intensity of the wireless signals, and pivotally connecting the wireless module to the external antenna through the pivot hinge to allow users to adjust the angle of the external antenna freely. The invention not only allows users to adjust the angle of the external antenna according to the conditions of receiving or transmitting wireless signals, but also overcoming the problem of having a too-large area of the external antenna that may hinder the use of the wireless module connected to other connectors.

### BRIEF DESCRIPTION OF THE DRAWINGS

FIG. 1 is an exploded view of a first preferred embodiment of the present invention;

FIG. 2 is a perspective view of the first preferred embodiment of the present invention;

FIG. 3 is a cross-sectional view of the first preferred embodiment of the present invention;

FIG. 4 is another cross-sectional view of the first preferred embodiment of the present invention;

FIG. 5 is another perspective view of the first preferred embodiment of the present invention;

FIG. 6 is a perspective view of a second preferred embodiment of the present invention;

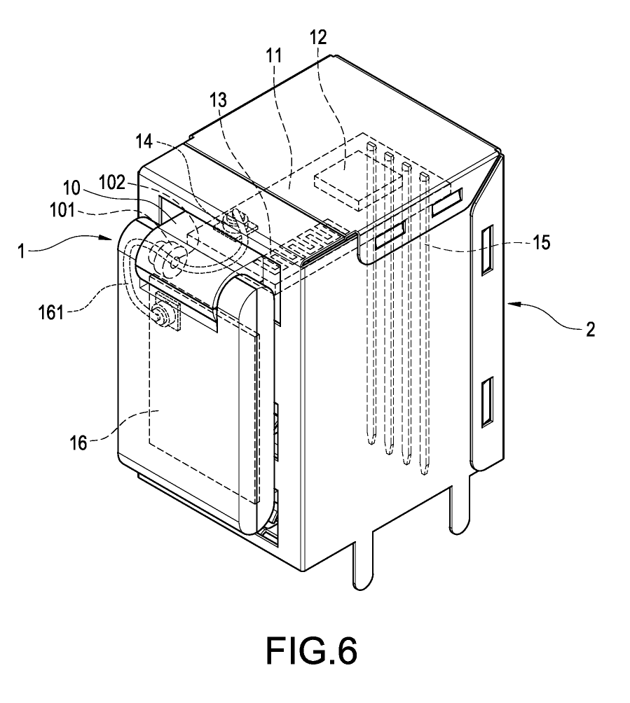

FIG. 7 is a cross-sectional view of the second preferred embodiment of the present invention; and

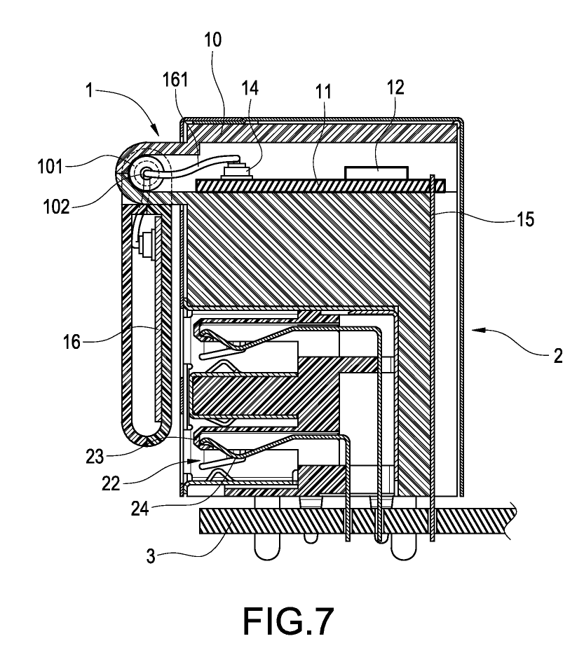

FIG. 8 is another cross-sectional view of the second preferred embodiment of the present invention.

### DESCRIPTION OF THE PREFERRED EMBODIMENTS

The details and technical contents of the present invention will become apparent with the detailed description of the following preferred embodiments accompanied with the illustration of the related drawings as follows. However, the drawings are provided for the purpose of illustrating the present invention only, but not intended for limiting the scope of the invention.

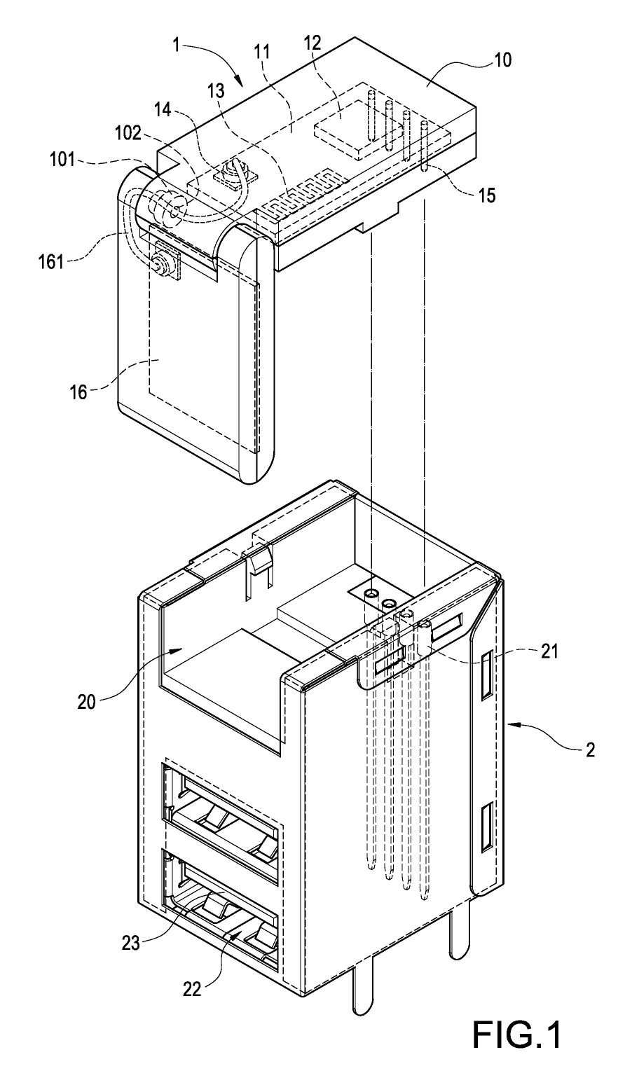

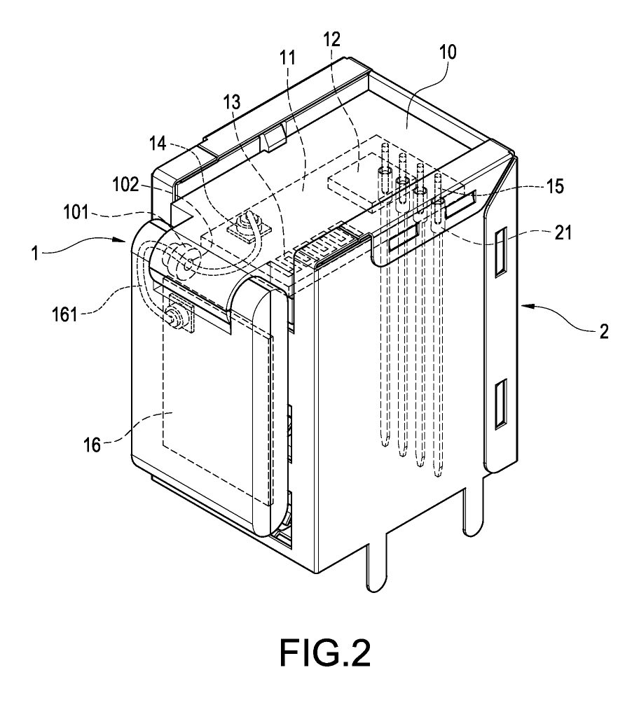

With reference to FIGS. 1 and 2 for an exploded view and a perspective view of a wireless module in accordance with the first preferred embodiment of the present invention respectively, the wireless module 1 comprises a printed circuit board 11, a wireless transmission chip 12, an antenna connector 14, and a plurality of conductive terminals 15, wherein the wireless transmission chip 12, the antenna connector 14, and the plurality of conductive terminals 15 are electrically coupled to the printed circuit board 11.

The wireless module 1 further comprises a casing 10, and the casing 10 has a containing space provided for installing the printed circuit board 11, the wireless transmission chip 12, the antenna connector 14, and the plurality of conductive terminals 15 therein. The conductive terminals 15 are electrically coupled to an end of the printed circuit board 11, and the casing 10 includes a pivot hinge 101 installed at an end away from the conductive terminals 15. The wireless module 1 includes an external antenna 16 pivotally coupled to the pivot hinge 101 of the casing 10, such that users can adjust the angle of the external antenna 16 through the pivot hinge 101 freely.

The external antenna 16 is a planar inverted F antenna (PIFA) or a film antenna, but the invention is not limited to these types of antennas only. The external antenna 16 is electrically coupled to the antenna connector 14 on the printed circuit board 11 through a connected circuit 161. More specifically, the casing 10 has a hole 102, and the connected circuit 161 is passed into the containing space of the casing 10 through the hole 102 to electrically couple the antenna connector 14.

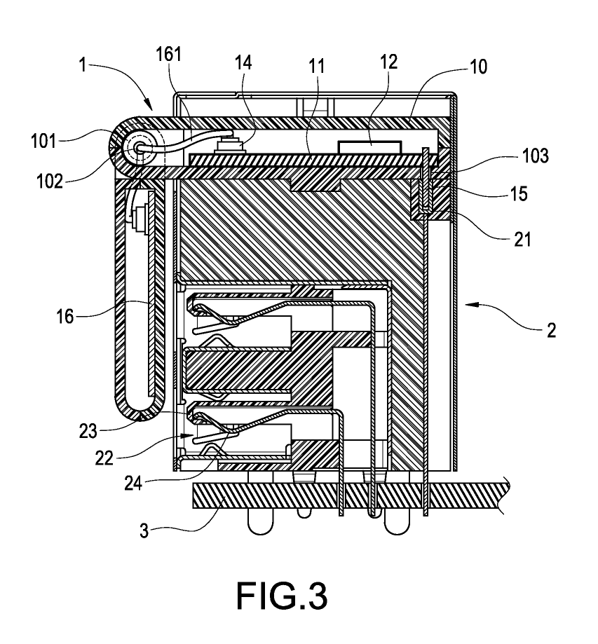

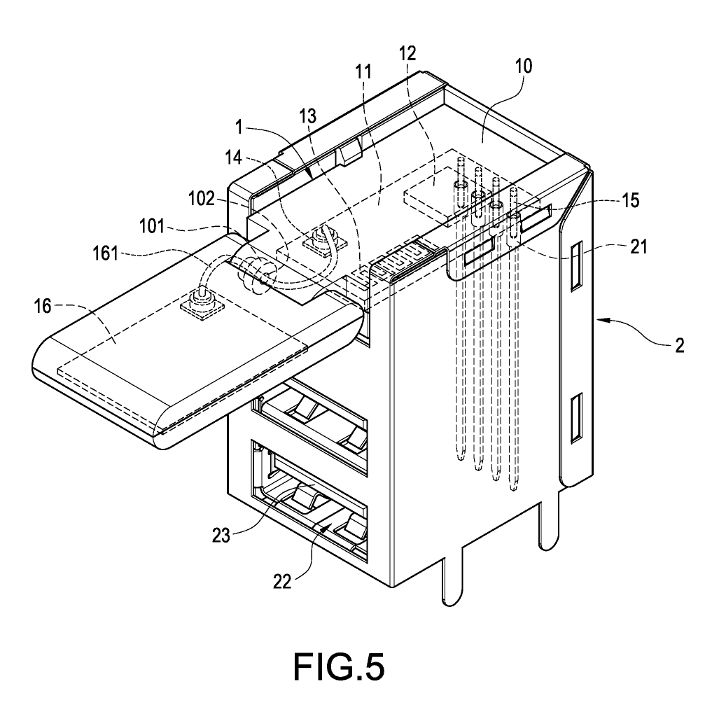

With reference to FIGS. 3 to 5 for cross-sectional views and a perspective view of the first preferred embodiment of the present invention respectively, the wireless module 1 is electrically coupled to an external electronic device (not shown in the figures) through the plurality of conductive terminals 15. In this preferred embodiment, the wireless module 1 is electrically coupled to a connector body 2 through the plurality of conductive terminals 15 and electrically coupled to a motherboard 3 of the external electronic device through the connector body 2. More specifically, at least one opening 103 is formed at the bottom of the casing 10, and the conductive terminals 15 are passed through the at least one opening 103 and protruded out from the casing 10 to electrically couple the connector body 2.

The connector body 2 comprises a through slot 20 formed thereon for containing the wireless module 1. More specifically, the wireless module 1 is installed into the through slot 20 through the casing 10. The connector body 2 further comprises a plurality of pin sockets 21 provided for electrically coupling the connector body 2 to the motherboard 3. When the wireless module 1 is installed in the through slot 20, the conductive terminals 15 on the wireless module 1 are electrically conducted with the plurality of the pin sockets 21, and thus the wireless module 1 can be electrically coupled to the motherboard 3 through the plurality of pin sockets 21.

The quantity of pin sockets 21 and the corresponding installation positions of the pin sockets 21 are the same as those of the plurality of conductive terminals 15 of the wireless module 1. In this preferred embodiment, both of the quantity of pin sockets 21 and the quantity of conductive terminals 15 are equal to four. However, the present invention is not limited to this quantity only.

The wireless module 1 is provided for receiving an electric signal transmitted from the motherboard 3, and after the wireless transmission chip 12 encodes the wireless signal, the wireless signal is transmitted to the outside through the external antenna 16. In addition, the wireless module 1 further receives an external wireless signal through the external antenna 16, and after the wireless transmission chip 12 decodes the wireless signal, the wireless signal is transmitted to the motherboard 3 through the plurality of conductive terminals 15.

In this preferred embodiment, the wireless module 1 further comprises an antenna unit 13 electrically coupled to the printed circuit board 11, and the wireless module 1 selectively receives/transmits a wireless signal through the antenna unit 13 and/or the external antenna 16. In addition, the wireless module 1 can use the antenna unit 13 and the external antenna 16 at the same time to transmit the wireless signal by different transmission methods to enhance the range of transmitting the wireless signal, so as to enhance the transmission performance of the wireless signal.

In the first preferred embodiment of the present invention as shown in FIGS. 1 to 5, the wireless module 1 with the external antenna 16 is disclosed, and the wireless module 1 can be detachably installed on the connector body 2. With reference to FIGS. to 8 for a perspective view and cross-sectional views in accordance with the second preferred embodiment of the present invention respectively, this preferred embodiment discloses a connector with the aforementioned wireless module 1, and the connector comprises the connector body 2 and the wireless module 1, and the connector body 2 and the wireless module 1 are integrally formed and cannot be detached from each other.

At least one containing slot 22 is concavely formed at a front end surface of the connector body 2, and each containing slot 22 includes a tongue 23 and a plurality of connecting terminals 24 disposed on the tongue 23, and the connector body 2 is electrically coupled to the motherboard 3 through the plurality of connecting terminals 24. Each containing slot 22 together with the tongue 23 and the plurality of connecting terminals 24 form a port. More specifically, the quantity of connecting terminals 24 is equal to four, and each containing slot 22 together with the tongue 23 and the plurality of connecting terminals 24 form a Universal Serial Bus (USB) port. Alternately, the quantity of connecting terminals 24 is also equal to seven, and each containing slot 22 together with the tongue 23 and the plurality of connecting terminals 24 form an External Serial Advance Technology Attachment (e-SATA) port. These ports are used as examples in the preferred embodiments for the purpose of illustrating the present invention, but the present invention is not limited to these ports only. The connector body 2 can have different types of ports according to actual requirements.

The connector body 2 has at least one through slot 20 formed on the at least one containing slot 22, and the wireless module 1 is installed in the through slot 20. In this preferred embodiment, the wireless module 1 comprises the casing 10, and the casing 10 contains the printed circuit board 11, and the wireless transmission chip 12, the antenna unit 13, the antenna connector 14, and the plurality of conductive terminals 15 that are electrically coupled to the printed circuit board 11. It is noteworthy that the connector body 2 of this preferred embodiment does not require any pin socket 21, and the conductive terminals 15 are passed through the connector body 2 and protruded out from the bottom of the connector body 2 to electrically couple the motherboard 3.

The casing 10 has the pivot hinge 101 installed at an end away from the plurality of conductive terminals 15, and the external antenna 16 is pivotally coupled to the pivot hinge 101 of the casing 10, and the casing 10 has a length slightly greater than the depth of the through slot 20. When the wireless module 1 is installed in the through slot 20, the pivot hinge 101 is protruded out from the through slot 20.

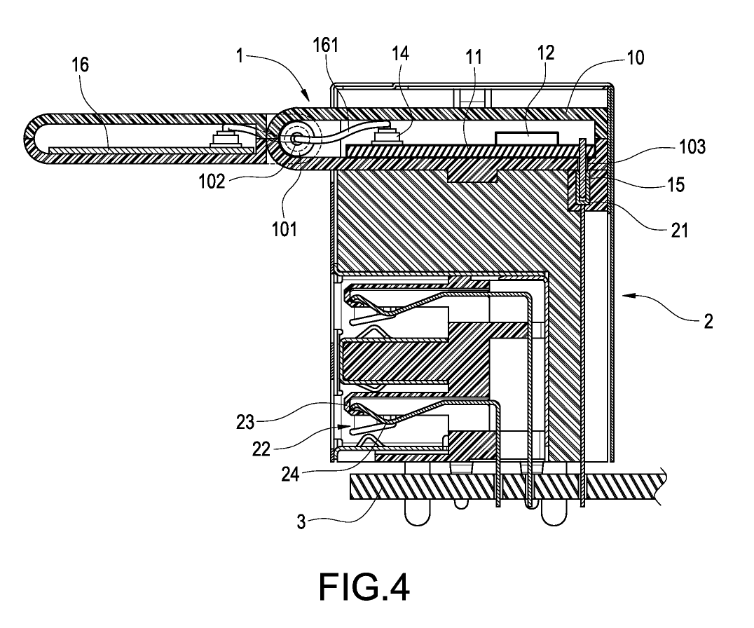

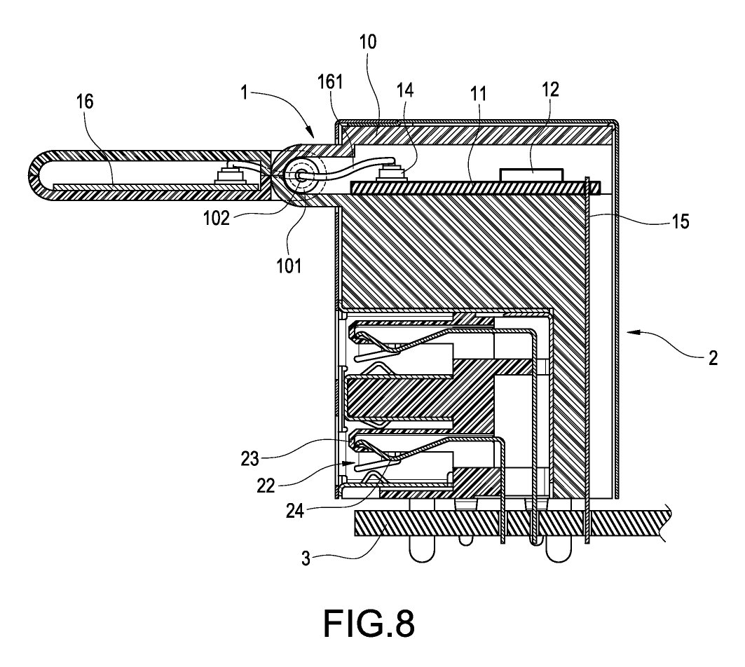

In summation of the description above, the external antenna 16 is installed outside the through slot 20 of the connector body 2 and provided for users to adjust the angle of the external antenna 16 freely. In FIGS. 4, 5 and 8, the users can change the transmitting strength of the wireless signal by using the pivot mechanism to adjust the angle of the external antenna 16. The connector with the wireless module 1 in accordance with the present invention will not hinder any port of the connector body 2 due to the installation of the external antenna 16.

While the invention has been described by means of specific embodiments, numerous modifications and variations could be made thereto by those ordinarily skilled in the art without departing from the scope and spirit of the invention set forth in the claims.

What is claimed is:

1. A wireless module with an external antenna, comprising:
a printed circuit board;
a plurality of conductive terminals, electrically coupled to an end of the printed circuit board and configured for electrically coupling the wireless module to an external electronic device;
a wireless transmission chip, electrically coupled to the printed circuit board and configured for encoding and decoding a wireless signal;
an antenna connector, electrically coupled to the printed circuit board;
a casing, having a containing space and configured for containing the printed circuit board, the plurality of conductive terminals, the wireless transmission chip, and the antenna connector, the casing including a pivot hinge installed at an end away from the plurality of conductive terminals; and
an external antenna, pivotally coupled to the pivot hinge of the casing and electrically coupled to the antenna connector through a connected circuit.

2. The wireless module with an external antenna as recited in claim 1, wherein a number of the conductive terminals is four.

3. The wireless module with an external antenna as recited in claim 1, wherein the casing has a hole formed thereon, and the connected circuit is passed into the containing space of the casing through the hole to electrically couple the antenna connector.

4. The wireless module with an external antenna as recited in claim 1, wherein the casing has at least one opening formed on a side of the bottom of the casing, and the conductive terminals are passed through the opening and protruded out from the casing to electrically couple the external electronic device.

5. The wireless module with an external antenna as recited in claim 1, further comprising an antenna unit electrically coupled to the printed circuit board, and the wireless module receives/transmits the wireless signal through the antenna unit or the external antenna.

6. A connector with a wireless module, for electrically coupling a motherboard of an external electronic device and the connector with the wireless module comprising:
a connector body, having at least one containing slot formed at a front surface of the connector body, and each containing slot including a tongue and a plurality of connecting terminals installed on the tongue, the connector being electrically coupled to the plurality of connecting terminals and the motherboard, the connector body having a through slot formed at the top of the at least one containing slot; and
a wireless module, installed in the through slot of the connector body, and comprising:
a printed circuit board;
a plurality of conductive terminals, electrically coupled to an end of the printed circuit board, passed through the connector body, and protruded out from the connector body to electrically couple the motherboard;
a wireless transmission chip, electrically coupled to the printed circuit board and configured for encoding and decoding a wireless signal;
an antenna connector, electrically coupled to the printed circuit board;
a casing, having a containing space, for containing the printed circuit board, the plurality of conductive terminals, the wireless transmission chip, and the antenna connector, the wireless module being installed in the through slot of the connector body through the casing, and the casing having a pivot hinge installed at an end away from the plurality of conductive terminals and protruded out from the through slot; and
an external antenna, pivotally coupled to the pivot hinge of the casing, and electrically coupled to the antenna connector through a connected circuit.

7. The connector with a wireless module as recited in claim 6, wherein the casing has a hole formed at the top of the casing, and the connected circuit is passed into the containing space of the casing through the hole to electrically couple the antenna connector.

8. The connector with a wireless module as recited in claim 6, wherein the casing has at least one opening formed on a side of the bottom of the casing, and the conductive terminals are passed through the opening and protruded out from the casing to electrically couple the external electronic device.

9. The connector with a wireless module as recited in claim 6, further comprising an antenna unit electrically coupled to the printed circuit board, and the wireless module is provided for receiving/transmitting the wireless signal through the antenna unit or the external antenna.

10. The connector with a wireless module as recited in claim 6, wherein a number of the connecting terminals is four or seven, and each of the containing slots together with the tongue and the plurality of connecting terminals jointly form a Universal Serial Bus (USB) port, or an External Serial Advance Technology Attachment (e-SATA) port.
